(19) United States
(12) Patent Application Publication
(10) Pub. No.: US 2002/0137307 A1
(43) Pub. Date: Sep. 26, 2002

(54) Method for forming isolation layer of semiconductor device

(76) Inventors: Chang Gyu Kim, Kyoungki-do (KR); Wan Shick Kim, Kyoungki-do (KR)

Correspondence Address: WILDMAN, HARROLD, ALLEN & DIXON, 225 WEST WACKER DRIVE, CHICAGO, IL, 60606, US

(21) Appl. No.: 10/001,314

(22) Filed: Nov. 14, 2001

(30) Foreign Application Priority Data
Mar. 24, 2001 (KR) 2001-15415

(51) Int. Cl. H01L 21/8238; H01L 21/336; H01L 21/302

(52) U.S. Cl. 438/432; 438/424; 438/221; 438/692; 438/296; 438/435

(57) ABSTRACT

A method for forming an isolation layer of a semiconductor device is disclosed. The method has a wet etching separately performed two times or more without a conventional chemical mechanical polishing process. In the method, a silicon substrate in which an active region and a field region are defined is provided, and a trench is formed in the silicon substrate within the field region. An insulating layer to be used as the isolation layer is then formed on the silicon substrate including the trench. Thus the trench is filled with the insulating layer. Next, a capping layer is formed on a resultant entire structure including the insulating layer, and selectively removed to expose an upper portion of the insulating layer in the active region. The exposed insulating layer in the active region is then removed by a first wet etching, and the residual capping layer is removed by a second wet etching. Accordingly, the isolation layer is obtained from the insulating layer remaining in the trench.

### BACKGROUND OF THE INVENTION

1. Field of the Invention

The present invention relates generally to a method for forming a semiconductor device. More particularly, the present invention relates to a method for forming an isolation layer of the semiconductor device, preferably adaptable to fabrication of a shallow trench isolation layer employed for electrically isolating unit devices from each other.

2. Description of the Related Art

In general, the semiconductor memory device has a plurality of cells integrated into a limited area. Each cell, composed of the unit devices such as a transistor and a capacitor, requires an electrical isolation from the other cells for independent operation characteristics.

As ways to realize an electrical isolation between the cells, a local oxidation of silicon (LOCOS) technology and a shallow trench isolation (STI) technology are well known in the art. The LOCOS technology grows a field oxide layer as a medium of isolation in a recess place of a silicon substrate, while the STI technology fills insulating material as an isolation medium in a vertically etched place of the silicon substrate.

In a conventional STI process, a trench mask pattern is formed on the silicon substrate, and an etching process using the trench mask pattern is then performed. Therefore, a trench is formed in a portion of the silicon substrate. Next, an insulating layer, preferably of oxide with a thickness of several thousands of angstrom, is deposited over the entire silicon substrate having the trench, and then removed from a top surface of the silicon substrate by a chemical mechanical polishing (CMP) process. Consequently, a shallow trench isolation layer for isolation is formed and planarized.

Since, contrary to a typical reflow process or a typical etch back process, the CMP process realize a more global blanket removal at a lower temperature, the CMP process is widely used for planarization technology and the STI technology.

During the CMP process, a surface of a wafer, for example, the insulating layer, is polished by chemical reaction and mechanical abrasion of polishing slurry and a polishing pad. Unfortunately, particles contained in the polishing slurry may be agglutinated and thereby produce scratches on the polished surface. In addition, waste or transformation of the polishing pad or a backing film used together with the polishing pad may undesirably affect the CMP process.

In the polishing slurry, the particles may vary in distribution, depending upon a storing method thereof, a mixing process with deionized water or chemicals such as surface-active agent, a pipe arrangement from a storing tank to a polishing apparatus, and a flow rate. Therefore, the particles are unstably dispersed in the slurry, so that a large particle may be formed by agglutination of the particles in the slurry.

Seriously, the agglutinated particle can produce the scratches on the surface of the wafer during the CMP process. Also, the scratches may tend to spread in a following cleaning process. Besides, grains of diamond used for a pad conditioner may be detached from the pad conditioner and then also produce the scratches.

Moreover, the polishing rate varies according to the number of wafers subjected to the polishing process or time required for the polishing process, which may cause a process margin to be lowered. Therefore, a sample polishing operation should be needed to certify process stability. The sample polishing may additionally require a dummy wafer processing step and a monitoring step for checking results in the preceding process, thereby lowering the rate of operation.

Furthermore, when the polishing amount does not reach the objective one, the polishing operation should be repeated to remove non-polished parts. On the other hand, when the polishing amount exceeds the objective one, an active device region may be damaged or the shallow trench isolation region may have a poor profile.

### SUMMARY OF THE INVENTION

It is therefore an object of the present invention to provide an improved method for forming an isolation layer of a semiconductor device, realizing an excellent surface uniformity through a simpler process without a conventional chemical mechanical polishing process, and thereby enhancing reliability of the device.

This and other objects in accordance with the present invention are attained by a method, which has a wet etching used two times or more to selectively and separately remove layers.

The method according to the present invention comprises providing a silicon substrate in which an active region and a field region are defined, and forming a trench in the silicon substrate within the field region. In the method of the present invention, an insulating layer to be used as the isolation layer is formed on the silicon substrate including the trench. Thus the trench is filled with the insulating layer. Next, a capping layer is formed on a resultant entire structure including the insulating layer, and selectively removed to expose an upper portion of the insulating layer within the active region. The exposed insulating layer within the active region is then removed, and the residual capping layer is removed. Accordingly, the isolation layer is obtained from the insulating layer remaining in the trench.

In the method, the insulating layer may have a first portion filled in the trench within the field region and a second portion formed on the silicon substrate within the active region. The first portion may be physically separated from the second portion. Preferably, a high density plasma undoped silicate glass (HDP-USG) layer may be used as the insulating layer, while a nitride layer may be used as the capping layer.

Furthermore, the selectively removing of the capping layer may use a reverse photo mask. Moreover, the removing of the exposed insulating layer and the removing of the residual capping layer may use respectively wet etching processes.

According to an alternate aspect of the present invention, another method is provided for forming an isolation layer of a semiconductor device. In the method, after a silicon substrate having an active region and a field region is provided, a pad oxide layer and a silicon nitride layer are sequentially formed on the silicon substrate. A trench is then formed in the silicon substrate to define the field region by selectively removing the silicon nitride layer, the pad oxide layer and an upper portion of the silicon substrate. Next, an insulating layer to be used as the isolation layer is formed on the silicon nitride layer and the trench, so that the trench is filled with the insulating layer. Next, a capping layer is formed on a resultant entire structure including the insulating layer, and selectively removed to expose an upper portion of the insulating layer within the active region. The exposed insulating layer within the active region is then removed, and the residual capping layer and the silicon nitride layer are also removed. The isolation layer is obtained from the insulating layer remaining in the trench after the pad oxide layer is removed.

According to another alternate aspect of the present invention, a method is provided for forming a shallow trench isolation layer of a semiconductor device. In the method, a silicon substrate having an active region and a field region is provided, and a pad oxide layer and a silicon nitride layer are sequentially formed on the silicon substrate. Then, a trench is formed in the silicon substrate to define the field region by selectively removing the silicon nitride layer, the pad oxide layer and an upper portion of the silicon substrate Next, a high density plasma undoped silicate glass (HDP-USG) layer is formed on the silicon nitride layer and the trench, so that the trench is filled with the HDP-USG layer. Then, a nitride layer is formed on a resultant entire structure including the HDP-USG layer, and a reverse photo mask is formed on the nitride layer to cover the field region and to expose the active region. Thereafter, the nitride layer is selectively removed to expose an upper portion of the HDP-USG layer within the active region by using the reverse photo mask as an etch barrier. The exposed HDP-USG layer within the active region is then removed by using a first wet etching after removing the reverse photo mask. Also, the residual nitride layer and the silicon nitride layer are removed by using a second wet etching. Next, the pad oxide layer is removed, so that the shallow trench isolation layer is obtained from the HDP-USG layer remaining in the trench.

### BRIEF DESCRIPTION OF THE DRAWINGS

FIGS. 1 through 7 are cross-sectional views showing a sequence of processes for forming an isolation layer of a semiconductor device according to an embodiment of the present invention.

### DETAILED DESCRIPTION OF THE INVENTION

The present invention will now be described more fully hereinafter with reference to accompanying drawings, in which preferred embodiments of the invention are shown. This invention, however, be embodied in many different forms and should not be construed as limited to the embodiments set forth herein.

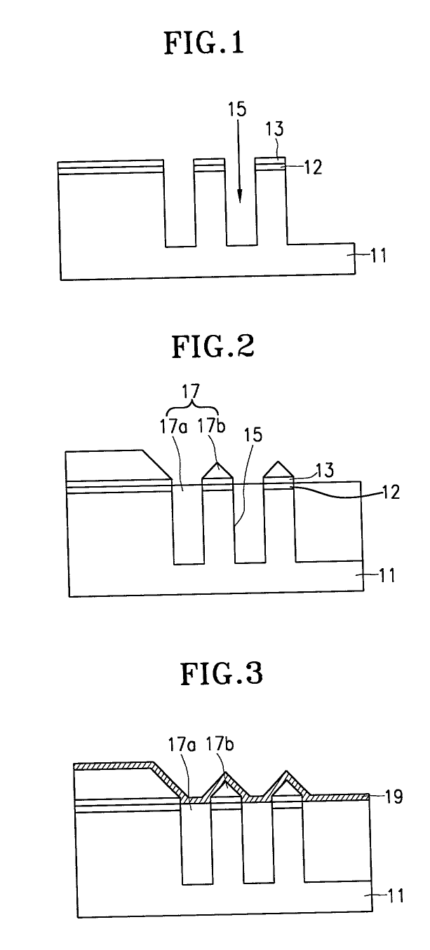

As shown in FIG. 1, after a silicon substrate 11 is provided, a pad oxide layer 12 and a silicon nitride layer 13 are sequentially formed on the silicon substrate 11. The silicon substrate 11 has an active region where a cell is formed and a field region where a trench 15 is to be formed for isolation between the adjacent cells. The pad oxide layer 12 is preferably formed with a thickness of several tens to hundreds angstrom by a thermal oxidation. The silicon nitride layer 13 is preferably formed with a thickness of hundreds angstrom by a chemical vapor deposition (CVD).

Then, a proper resist pattern (not shown) is formed on the silicon nitride layer 13 through a photolithographic process. For example, a photoresist layer or a hard oxide layer may be employed for the resist pattern. With the resist pattern being used as a mask, the silicon nitride layer 13 and the pad oxide layer 12 are selectively removed and an upper portion of the silicon substrate 11 is also selectively removed. Thus a trench 15 is formed in the silicon substrate 11 within the field region.

Next, the resist pattern is removed and the silicon substrate 11 is cleaned. The silicon substrate 11 exposed through the silicon nitride layer 13 is then thermally oxidized, so that an oxide layer (not shown) is formed on an inner wall of the trench 15.

Thereafter, as shown in FIG. 2, an insulating layer 17 is deposited over the entire silicon substrate 11 by a deposition such as a chemical vapor deposition (CVD) Thereby, the trench 15 is completely filled with a first portion 17a of the insulating layer, and further, the silicon nitride layer 13 in the active region is almost covered with a second portion 17b of the insulating layer.

Preferably, a top surface of the insulating layer 17a in the trench 15 is lower than that of the silicon nitride layer 13. Therefore, the insulating layer 17a in the trench 15 is physically separated from the insulating layer 17b in the active region. As the preferred insulating layer 17, a high density plasma undoped silicate glass (HDP-USG) layer may be used.

After the deposition of the insulating layer 17, as shown in FIG. 3, a capping layer 19 is deposited with a certain thickness on a resultant entire structure including the insulating layer 17. Preferably, a nitride layer is used as the capping layer 19.

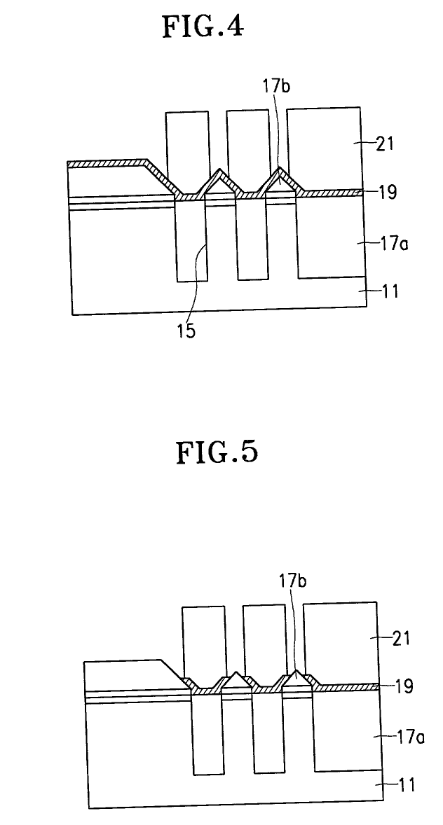

Next, a reverse photo process is performed. As exemplarily shown in FIG. 4, a reverse photo mask 21 is formed with pattern on the capping layer 19 so that the field region with the trench 15 is covered therewith and the active region is exposed therethrough.

Then, with the reverse photo mask 21 being used as an etch barrier, an etching process is carried out to selectively remove the capping layer 19. Therefore, as depicted in FIG. 5, the capping layer 19 is removed from the active region, and an upper portion of the insulating layer 17b in the active region is exposed through the remaining capping layer 19.

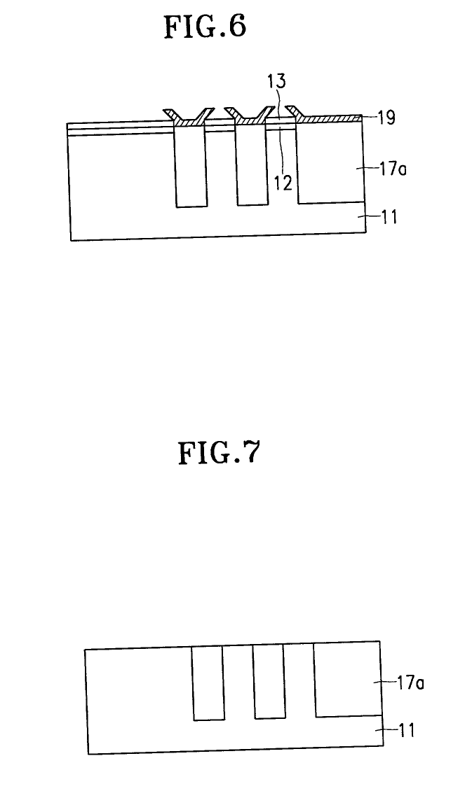

Next, as shown in FIG. 6, the exposed insulating layer in the active region is selectively removed by a wet etching process. Such a wet etching process uses an etchant having a high selectivity to nitride and thus allowing removal of oxide. Diluted hydrogen fluoride (DHF) is preferably used as the etchant of the wet etching. In particular, during the wet etching, the insulating layer 17a in the trench is not damaged because of the residual capping layer 19. The reverse photo mask 21 may be removed before removing the insulating layer 17b.

In an alternative embodiment of the present invention, the reverse photo mask 21 only may be used for selectively removing the insulating layer in the active region without employing the capping layer 19 of nitride.

After the wet etching to oxide, a second wet etching process is performed to wholly remove the residual capping layer 19 and the silicon nitride layer 13. The second wet etching uses an etchant, such as phosphoric acid, having a high selectivity to oxide and thus allowing removal of nitride.

The pad oxide layer 12 is then removed. Accordingly, as shown in FIG. 7, a desired isolation layer is obtained from the insulating layer 17a remaining in the trench 15. If necessary, the insulating layer 17a in the trench may be partially etched to adjust a height thereof by using an etchant having a high selectivity to nitride.

As described above, the present invention does not use the conventional CMP process during formation of the isolation layer. Therefore, undesired scratches are prevented from being produced on the surface of the wafer due to polishing particles, which causes an improvement in reliability and productivity of the device, a reduction in fabrication cost of the device, and an increase in operation rate of the apparatus

What is claimed is:

1. A method for forming an isolation layer of a semiconductor device, comprising:
providing a silicon substrate in which an active region and a field region are defined;
forming a trench in the silicon substrate within the field region;
forming an insulating layer to be used as the isolation layer on the silicon substrate including the trench, thereby filling the trench with the insulating layer;
forming a capping layer on a resultant entire structure including the insulating layer;
selectively removing the capping layer to expose an upper portion of the insulating layer within the active region;
removing the exposed insulating layer within the active region; and
removing the residual capping layer, so that the isolation layer is obtained from the insulating layer remaining in the trench.

2. The method of claim 1, wherein the insulating layer has a first portion filled in the trench within the field region and a second portion formed on the silicon substrate within the active region, and wherein the first portion is physically separated from the second portion.

3. The method of claim 1, wherein the insulating layer includes a high density plasma undoped silicate glass (HDP-USG) layer.

4. The method of claim 1, wherein the capping layer includes a nitride layer.

5. The method of claim 1, wherein the selectively removing of the capping layer uses a reverse photo mask.

6. The method of claim 1, wherein the removing of the exposed insulating layer and the removing of the residual capping layer use respectively wet etching processes.

7. A method for forming an isolation layer of a semiconductor device, comprising:
providing a silicon substrate having an active region and a field region;
sequentially forming a pad oxide layer and a silicon nitride layer on the silicon substrate;
forming a trench in the silicon substrate to define the field region by selectively removing the silicon nitride layer, the pad oxide layer and an upper portion of the silicon substrate;
forming an insulating layer to be used as the isolation layer on the silicon nitride layer and the trench, thereby filling the trench with the insulating layer;
forming a capping layer on a resultant entire structure including the insulating layer;
selectively removing the capping layer to expose an upper portion of the insulating layer within the active region;
removing the exposed insulating layer within the active region;
removing the residual capping layer and the silicon nitride layer; and
removing the pad oxide layer, so that the isolation layer is obtained from the insulating layer remaining in the trench.

8. The method of claim 7, wherein the insulating layer has a first portion filled in the trench within the field region and a second portion formed on the silicon nitride layer within the active region, and wherein the first portion is physically separated from the second portion.

9. The method of claim 7, wherein the insulating layer includes a high density plasma undoped silicate glass (HDP-USG) layer.

10. The method of claim 7, wherein the capping layer includes a nitride layer.

11. The method of claim 7, wherein the selectively removing of the capping layer uses a reverse photo mask.

12. The method of claim 7, wherein the removing of the exposed insulating layer uses a first wet etching.

13. The method of claim 7, wherein the removing of the residual capping layer and the silicon nitride layer uses a second wet etching.

14. A method for forming a shallow trench isolation layer of a semiconductor device, comprising:
providing a silicon substrate having an active region and a field region;
sequentially forming a pad oxide layer and a silicon nitride layer on the silicon substrate;
forming a trench in the silicon substrate to define the field region by selectively removing the silicon nitride layer, the pad oxide layer and an upper portion of the silicon substrate;
forming a high density plasma undoped silicate glass (HDP-USG) layer to be used as the shallow trench isolation layer on the silicon nitride layer and the trench, thereby filling the trench with the HDP-USG layer;
forming a nitride layer on a resultant entire structure including the HDP-USG layer;
forming a reverse photo mask on the nitride layer to cover the field region and to expose the active region;
selectively removing the nitride layer to expose an upper portion of the HDP-USG layer within the active region by using the reverse photo mask as an etch barrier;
removing the exposed HDP-USG layer within the active region by using a first wet etching after removing the reverse photo mask;
removing the residual nitride layer and the silicon nitride layer by using a second wet etching; and
removing the pad oxide layer, so that the shallow trench isolation layer is obtained from the HDP-USG layer remaining in the trench.

15. The method of claim 14, wherein the HDP-USG layer has a first portion filled in the trench within the field region and a second portion formed on the silicon nitride layer within the active region, and wherein the first portion is physically separated from the second portion.
